(19) United States
(12) Patent Application Publication
(10) Pub. No.: US 2026/0370024 A1
(43) Pub. Date: Nov. 19, 2026

(54) BATTERY CHARGER

(71) Applicant: MILWAUKEE ELECTRIC TOOL CORPORATION, Brookfield, WI (US)

(72) Inventors: Matthew J. Herro, Pewaukee, WI (US); Anderson J. Ernst, Seal Beach, CA (US); Carson G. Taylor, Madison, WI (US); Keith G. Koch, Kenosha, WI (US); Jacob D. Rosenthal, Brookfield, WI (US); Joel D. Snyder, Menomonee Falls, WI (US)

(21) Appl. No.: 19/678,640

(22) Filed: May 15, 2026

Related U.S. Application Data
(60) Provisional application No. 63/806,398, filed on May 15, 2025.

(51) Int. Cl. H02J 7/70; H05K 7/20; H02J 7/50

(52) U.S. Cl. CPC H02J 7/751; H05K 7/20909; H02J 7/50

(57) ABSTRACT

A battery charger includes a housing assembly, a printed circuit board assembly with charging electronics, and a central frame directly coupled to the printed circuit board assembly. A fan generates airflow through the housing and is directly coupled to the central frame. The central frame is directly fastened to the housing assembly. The airflow cools the printed circuit board assembly and the battery pack when coupled to the housing assembly. The housing assembly may include a base housing and an upper housing, with the upper housing directly fastened to the central frame and the base housing fastened to the upper housing. This design provides efficient cooling and improved manufacturability.

### CROSS-REFERENCE TO RELATED APPLICATIONS

This application claims priority to U.S. Provisional Patent Application No. 63/806,398, filed May 15, 2025, the entire content of which is incorporated herein by reference.

### FIELD

The present disclosure relates to battery chargers, and more particularly, a frame and housing assembly for a battery charger.

### BACKGROUND

Previous approaches to battery chargers have typically included a printed circuit board assembly directly mounted to a housing assembly, which can lead to increased complexity and cost in the manufacturing process. Additionally, the direct mounting of the printed circuit board assembly to the housing assembly can also result in a less efficient cooling system, as the heat generated by the charging electronics can become trapped within the housing assembly.

Some previous approaches have attempted to address the issue of cooling by incorporating a fan into the battery charger. However, these fans have often been mounted directly to the housing assembly, rather than being directly coupled to a central frame. This can result in a less efficient airflow through the housing, as the fan may not be able to direct the airflow in a targeted manner. Furthermore, the mounting of the fan directly to the housing assembly can also lead to increased vibration and noise, which can be detrimental to the overall performance and lifespan of the battery charger.

### SUMMARY

In some aspects, the techniques described herein relate to a battery charger operable to charge a battery pack, the battery charger including: a housing assembly; a printed circuit board assembly positioned within the housing assembly, the printed circuit board assembly including charging electronics operable to output a charging current to charge the battery pack; a central frame positioned within the housing assembly and directly coupled to the printed circuit board assembly; and a fan operable to generate an airflow through the housing assembly, the fan directly coupled to the central frame; wherein the central frame is directly fastened to the housing assembly.

In some aspects, the techniques described herein relate to a battery charger, wherein: the housing assembly includes a base housing and an upper housing; the upper housing is directly fastened to the central frame; and the base housing is fastened to the upper housing.

In some aspects, the techniques described herein relate to a battery charger, wherein a portion of the central frame is clamped between the base housing and the upper housing.

In some aspects, the techniques described herein relate to a battery charger, wherein the central frame defines a rim that contacts and surrounds an outer periphery of the printed circuit board assembly.

In some aspects, the techniques described herein relate to a battery charger, wherein the printed circuit board assembly is mounted to the rim using threaded fasteners.

In some aspects, the techniques described herein relate to a battery charger, wherein the fan is mounted to a fan mount defined by the central frame.

In some aspects, the techniques described herein relate to a battery charger, wherein the airflow actively cools the printed circuit board assembly, and wherein the airflow also actively cools the battery pack when the battery pack is coupled to the housing assembly.

In some aspects, the techniques described herein relate to a battery charger operable to charge a battery pack, the battery charger including: a housing assembly; a printed circuit board assembly positioned within the housing assembly and including charging electronics operable to output a charging current to charge the battery pack; a central frame positioned within the housing assembly and directly coupled to the printed circuit board assembly; and a fan operable to generate an airflow through the housing assembly; wherein the airflow actively cools the printed circuit board assembly; and wherein the airflow actively cools the battery pack when the battery pack is coupled to the housing assembly.

In some aspects, the techniques described herein relate to a battery charger, wherein: the housing assembly includes a base housing and an upper housing; the upper housing is directly fastened to the central frame; and the base housing is fastened to the upper housing.

In some aspects, the techniques described herein relate to a battery charger, wherein: the central frame includes a fan mount and a duct wall; the base housing defines a plurality of inlet apertures; and an airflow passageway is defined between the duct wall and the base housing and extends from the plurality of inlet apertures to the fan mount.

In some aspects, the techniques described herein relate to a battery charger, further including a plenum defined by the upper housing and the fan mount and positioned downstream of the fan.

In some aspects, the techniques described herein relate to a battery charger, wherein the upper housing further defines an outlet aperture and a battery receptacle configured to engage the battery pack, and wherein the airflow exits the plenum through the outlet aperture and toward the battery pack.

In some aspects, the techniques described herein relate to a battery charger, wherein the fan mount divides the airflow passageway from the plenum.

In some aspects, the techniques described herein relate to a battery charger, wherein the charging electronics include a controller configured to selectively activate the fan in response to a detected temperature of the printed circuit board assembly exceeding a threshold temperature.

In some aspects, the techniques described herein relate to a battery charger operable to charge a battery pack, the battery charger including: a housing assembly having a base housing and an upper housing; a central charging assembly positioned within the housing assembly, the central charging assembly including: a central frame, a printed circuit board assembly mounted to the central frame, and a fan mounted to the central frame; and a battery receptacle mounted to the central frame and configured to removably couple to the battery pack.

In some aspects, the techniques described herein relate to a battery charger, wherein the central frame includes a sleeve defining at least portion of the battery receptacle.

In some aspects, the techniques described herein relate to a battery charger, wherein the upper housing is fastened directly to the central frame independently of the base housing.

In some aspects, the techniques described herein relate to a battery charger, wherein a portion of the central frame is clamped between the base housing and the upper housing.

In some aspects, the techniques described herein relate to a battery charger, wherein: the fan is operable to generate an airflow through the housing assembly; the airflow actively cools the printed circuit board assembly; and the airflow actively cools the battery pack when the battery pack is coupled to the battery receptacle.

In some aspects, the techniques described herein relate to a battery charger, wherein the central frame defines a rim that contacts and surrounds an outer periphery of the printed circuit board assembly.

Other aspects of the disclosure will become apparent by consideration of the detailed description and accompanying drawings.

### BRIEF DESCRIPTION OF THE DRAWINGS

FIG. 1 is a perspective view of a battery charger according to an embodiment of the disclosure.

FIG. 2 is a perspective view of a battery pack of a first type.

FIG. 3 is a perspective view of a battery pack of a second type.

FIG. 4 is a partially exploded perspective view of the battery charger of FIG. 1.

FIG. 5 is a perspective view of a charging assembly of the battery charger of FIG. 1.

FIG. 6 is a cross-sectional view of the battery charger of FIG. 1 taken along line 6—6 of FIG. 4.

FIG. 7 is a cross-sectional view of the battery charger of FIG. 1 taken along line 7—7 of FIG. 1.

FIGS. 8 and 9 are perspective views of a central frame of the battery charger of FIG. 1.

Before any independent embodiments of the disclosure are explained in detail, it is to be understood that the disclosure is not limited in its application to the details of construction and the arrangement of components set forth in the following description or illustrated in the following drawings. The disclosure is capable of other independent embodiments and of being practiced or of being carried out in various ways.

Use of “including” and “comprising” and variations thereof as used herein is meant to encompass the items listed thereafter and equivalents thereof as well as additional items. Use of “consisting of” and variations thereof as used herein is meant to encompass only the items listed thereafter and equivalents thereof.

Relative terminology, such as, for example, “about”, “approximately”, “substantially”, etc., used in connection with a quantity or condition would be understood by those of ordinary skill to be inclusive of the stated value and has the meaning dictated by the context (for example, the term includes at least the degree of error associated with the measurement of, tolerances (e.g., manufacturing, assembly, use, etc.) associated with the particular value, etc.). Such terminology should also be considered as disclosing the range defined by the absolute values of the two endpoints. For example, the expression “from about 2 to about 4” also discloses the range “from 2 to 4.” The relative terminology may refer to plus or minus a percentage (e.g., 1%, 5%, 10% or more) of an indicated value.

Also, the functionality described herein as being performed by one component may be performed by multiple components in a distributed manner. Likewise, functionality performed by multiple components may be consolidated and performed by a single component. Similarly, a component described as performing particular functionality may also perform additional functionality not described herein. For example, a device or structure that is “configured” in a certain way is configured in at least that way but may also be configured in ways that are not listed.

Furthermore, some embodiments described herein may include one or more electronic processors configured to perform the described functionality by executing instructions stored in a non-transitory, computer-readable medium. Similarly, embodiments described herein may be implemented as a non-transitory, computer-readable medium storing instructions executable by one or more electronic processors to perform the described functionality. As used in the present application, “non-transitory computer-readable medium” comprises all computer-readable media but does not consist of a transitory, propagating signal. Accordingly, a non-transitory computer-readable medium may include, for example, a hard disk, a CD-ROM, an optical storage device, a magnetic storage device, a ROM (Read Only Memory), a RAM (Random Access Memory), register memory, a processor cache, or any combination thereof.

Many of the modules and logical structures described are capable of being implemented in software executed by a microprocessor or a similar device or of being implemented in hardware using a variety of components including, for example, application-specific integrated circuits (“ASICs”). Terms like “controller” and “module” may include or refer to both hardware and/or software. Capitalized terms conform to common practices and help correlate the description with the coding examples, equations, and/or drawings. However, no specific meaning is implied or should be inferred simply due to the use of capitalization. Thus, the claims should not be limited to the specific examples or terminology or to any specific hardware or software implementation or combination of software or hardware.

### DETAILED DESCRIPTION

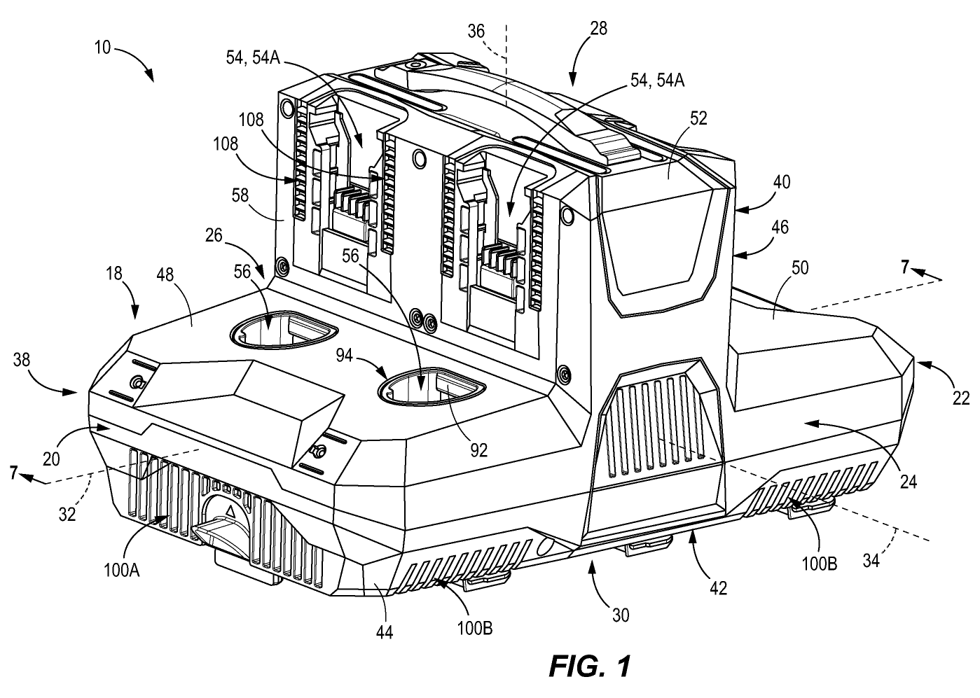

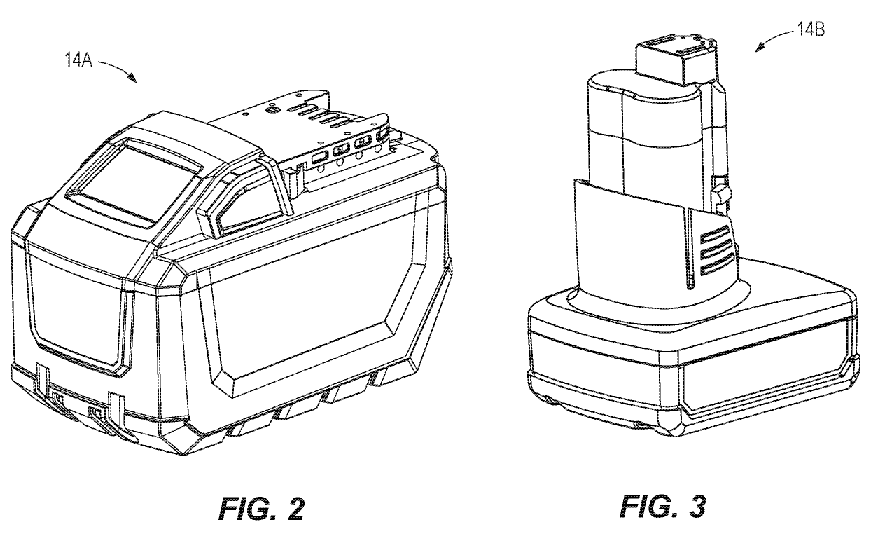

FIG. 1 illustrates a battery charger 10 operable to charge one or more battery packs. The battery charger 10 is also operable to provide active cooling to itself and to the battery packs. In the illustrated construction, the battery charger 10 is operable to charge a first battery pack 14A of a first type (FIG. 2). More specifically, the battery charger 10 is operable to charge up to four first battery packs 14A simultaneously. The battery charger 10 is also operable to charge a second battery pack 14B of a second type (FIG. 3). More specifically, the battery charger 10 is operable to charge up to two second battery packs 14B simultaneously. The illustrated battery charger 10 may be operable to charge a high-output battery pack (e.g., having a current capacity of 12 amp-hours (Ah) or more), which requires about 3 times the power of typical chargers, in as little as 45 minutes.

The battery pack type may be defined by nominal voltage, current capacity, connection configuration (e.g., “tower” vs. “slide-on”, or two different slide-on interfaces), etc., of the battery pack 14A, 14B. For example, the first battery pack 14A may be a high-output battery pack and may have a nominal voltage of 18V and a slide-on configuration. The second battery pack 14B may have a nominal voltage of about 12 volts (V) and a tower configuration. In other constructions (not shown), the battery packs 14A, 14B may be the same type of battery pack.

Each battery pack 14A, 14B is connectable to and operable to power various motorized power tools (e.g., a cut-off saw, a miter saw, a table saw, a core drill, an auger, a breaker, a demolition hammer, a compactor, a vibrator, a compressor, a drain cleaner, a welder, a cable tugger, a pump, etc.), outdoor tools (e.g., a chain saw, a string trimmer, a hedge trimmer, a blower, a lawn mower, etc.), other motorized devices (e.g., vehicles, utility carts, a material handling cart, etc.), and non-motorized electrical devices (e.g., a power supply, a light, an AC/DC adapter, a generator, etc.).

With reference to FIG. 1, in one embodiment, the battery charger 10 includes a housing assembly 18 having a first end 20, a second end 22 opposite the first end 20, a front side 24, a rear side 26 opposite the front side 24, a top side 28, and a bottom side 30 opposite the top side 28. The housing assembly 18 defines a longitudinal axis or first axis 32 that extends generally between the first end 20 and the second end 22. The housing assembly 18 also defines a lateral axis or second axis 34 that extends generally between the front side 24 and the rear side 26, and generally perpendicular to the first axis 32. The housing assembly 18 further defines a vertical axis or third axis 36 that extends generally between the top side 28 and the bottom side 30.

With continued reference to FIG. 1, the housing assembly 18 includes a base portion 38 and a central raised portion 40. The base portion 38 generally extends from the first end 20 to the second end 22 and from the front side 24 to the rear side 26. The base portion 38 generally defines a flat bottom surface 42 at the bottom side 30, which rests against or proximate to a support surface (e.g., a ground surface, a tabletop, etc.). The central raised portion 40 protrudes upwardly from a central region of the base portion 38 and generally extends from the front side 24 to the rear side 26 and from the base portion 38 to the top side 28.

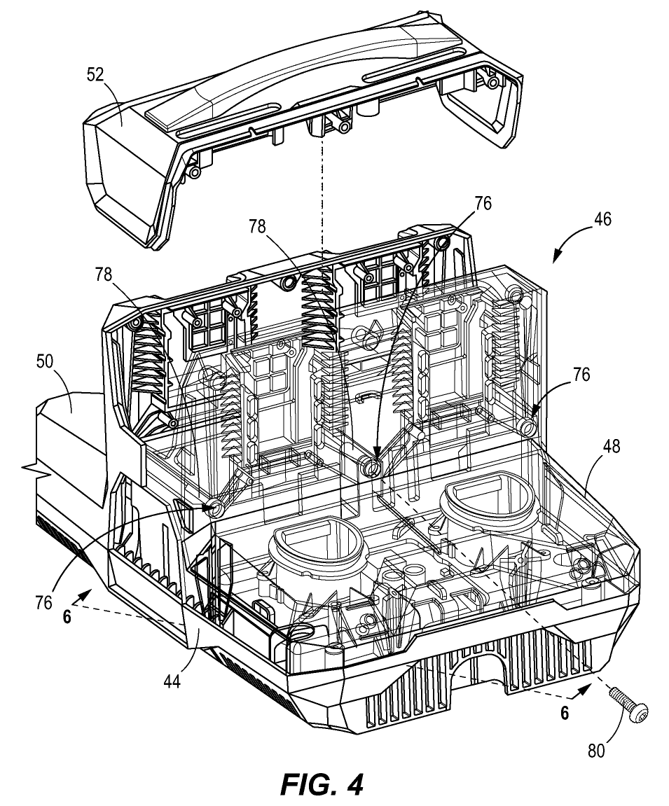

With reference to FIGS. 1 and 4, the housing assembly 18 includes a base housing 44 and an upper housing 46 coupled to the base housing 44. The base housing 44 and the upper housing 46 each partially define the base portion 38. The upper housing 46 completely or substantially defines the central raised portion 40. The upper housing 46 includes a first upper housing member 48, a second upper housing member 50, and a central upper housing member 52 positioned between the first and second upper housing members 48, 50, and coupled thereto.

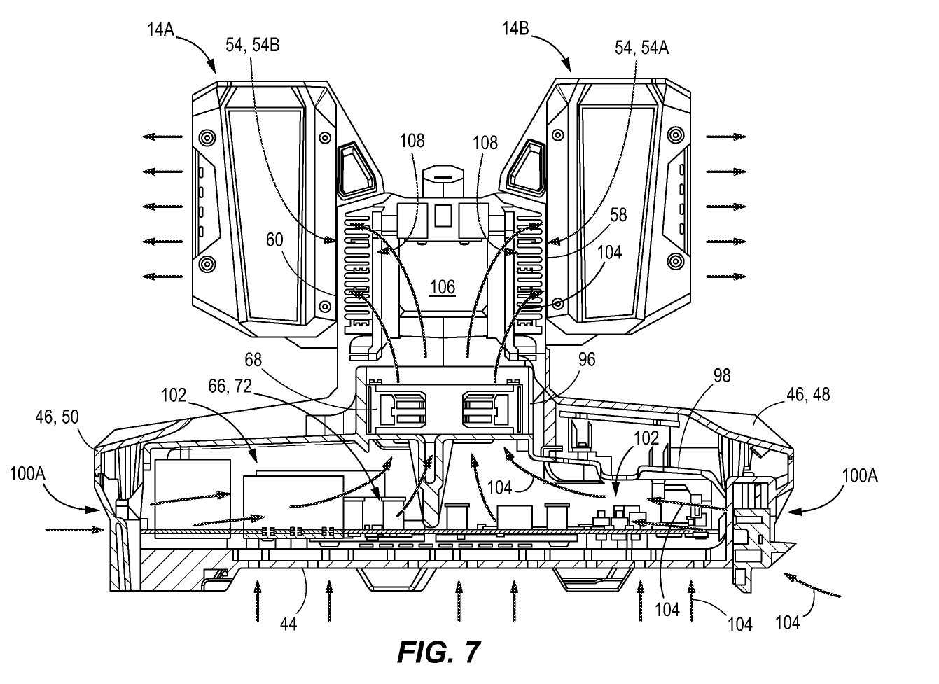

The battery charger 10 includes first battery receptacles 54 and second battery receptacles 56. The first battery receptacles 54 are operable to selectively and removably couple to the first battery pack 14A to form a mechanical and electrical connection therewith. The second battery receptacles 56 are operable to selectively and removably couple to the second battery pack 14B to form a mechanical and electrical connection therewith. In the illustrated embodiment, the battery charger 10 includes four first battery receptacles 54, all of which are located in the central raised portion 40. The battery charger 10 also includes two second battery receptacles 56, both of which are located in the base portion 38. The battery charger 10 is operable to charge the first battery packs 14A when the first battery packs 14A are coupled to the first battery receptacles 54, and is operable to charge the second battery packs 14B when the second battery packs 14B are coupled to the second battery receptacles 56. The central raised portion 40 includes a first vertical surface 58 facing toward the first end 20 and a second vertical surface 60 (FIG. 7) facing toward the second end 22. Two first battery receptacles 54A are located in the first vertical surface 58, and two first battery receptacles 54B (FIG. 7) are located in the second vertical surface 60. The first battery receptacles 54A are proximate to and generally face toward the second battery receptacles 56.

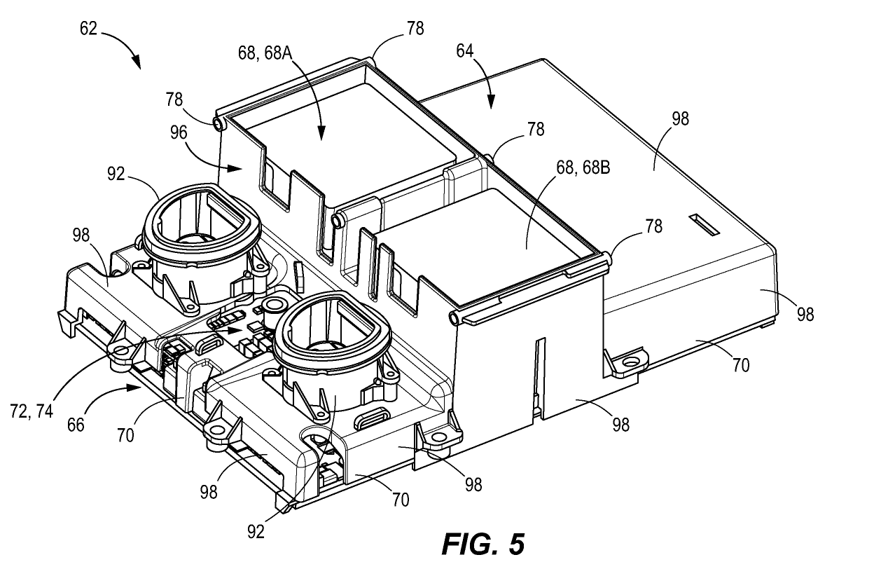

With reference to FIGS. 5 and 7, the battery charger 10 further includes a central charging assembly 62 located within the housing assembly 18. The central charging assembly 62 includes a central frame 64 (or PCBA frame 64) positioned within and directly coupled to the housing assembly 18 and supporting multiple internal components of the battery charger 10. The central charging assembly 62 also includes a printed circuit board assembly 66 (or PCBA 66) coupled to and supported by the central frame 64. The central charging assembly 62 further includes one or more fans 68 (two fans 68 are illustrated) that are operable to generate a cooling airflow to actively cool the PCBA 66 and the first and second battery packs 14A, 14B.

The central frame 64 includes a rim 70 that is generally rectangular and has a shape corresponding to a shape of the PCBA 66. The PCBA 66 couples to the central frame 64 at or near the rim 70. The PCBA 66 can be secured to the rim 70 via threaded fasteners (not shown). In other embodiments, the PCBA 66 can be secured to the rim 70 by snap fit, heat staking, slotted receptacles, adhesive, or other means. In some embodiments, a damping material, such as elastomeric dampers (not shown), can be positioned between the PCBA 66 and the rim 70 to attenuate transmission of vibrations to the PCBA 66.

The PCBA 66 includes charging electronics 72 operable to output a charging current to the first and second battery packs 14A, 14B to charge the first and second battery packs 14A, 14B when coupled to the receptacles 54, 56. The charging electronics 72 can connect to an external power source, such as an AC power outlet, via a power cord (not shown). For example, the charging electronics 72 are operable to convert an alternating current to a direct current. The charging electronics 72 can include, for example, a transformer and other circuitry to rectify and condition AC power and output a DC charging current to one or more of the first and second battery packs 14A, 14B via the receptacles 54, 56. In other embodiments, the charging electronics 72 are operable to draw power from a higher voltage DC source (not shown) to effect DC-to-DC charging.

The charging electronics 72 also include a microcontroller operable to control the charging circuits for charging the battery pack(s) 14A, 14B coupled to one or more of the receptacles 54, 56. For example, the charging circuits may include controllable power switching elements (e.g., field effect transistors, IGBTs, and the like) which the microcontroller 74 selectively enables to provide power from the charging electronics 72 to the respective battery packs 14A, 14B. The microcontroller 74 may also detect or monitor the temperatures of the PCBA 66 and/or the battery pack(s) 14A, 14B based on an output signal from one or more temperature sensors (not shown). Based on the temperatures detected, the microcontroller 74 activates and controls one or both of the fans 68 to provide active cooling, as described in further detail below. The microcontroller 74 includes an electronic processor and a memory storing instructions that are executed by the electronic processor to implement the functions of the microcontroller 74 described herein.

With reference to FIGS. 1, 4, and 5, the housing assembly 18 mounts directly to the central frame 64. Specifically, the upper housing 46 defines mounting apertures 76 which align with corresponding screw bosses 78 formed on the central frame 64. Threaded fasteners 80 pass through the mounting apertures 76 and tighten directly into the screw bosses 78. In some embodiments, the threaded fasteners 80 are self-tapping and create threads in the screw bosses 78 during installation. In other embodiments, the screw bosses 78 may be pre-threaded to engage the threads of the threaded fasteners 80. This allows the upper housing 46 to be split into multiple parts, i.e., the first upper housing member 48 and the second upper housing member 50, because the first and second upper housing members 48, 50 can independently be fastened directly to the central frame 64. This improves manufacturability and assembly of the battery charger 10.

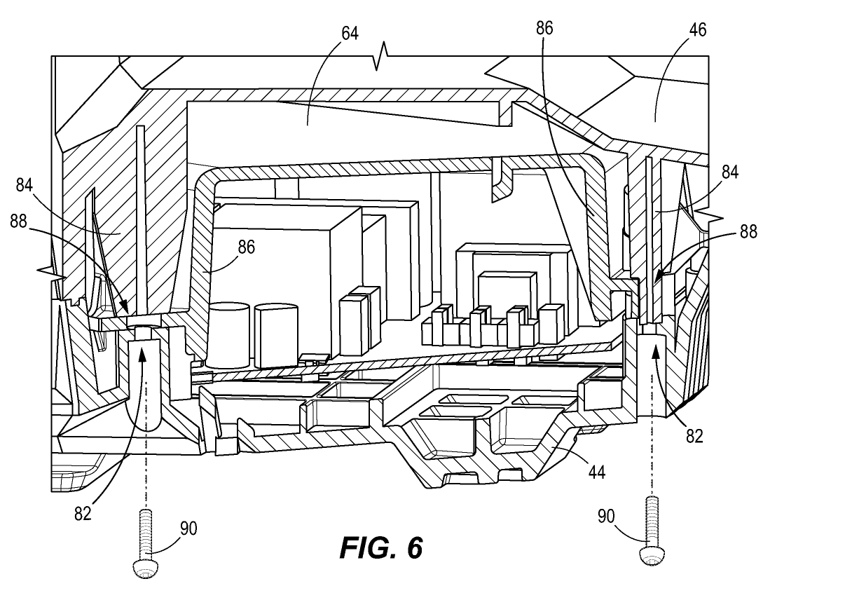

The base housing 44 also mounts directly to the upper housing 46 with portions of the central frame 64 being captured or clamped therebetween. As shown in FIG. 6, the base housing 44 defines mounting apertures 82 which align with corresponding screw bosses 84 formed on the upper housing 46. The central frame 64 includes mounting structures 86 which are clamped or otherwise disposed between the base housing 44 and the screw bosses 84 of the upper housing 46. The mounting structures 86 define mounting apertures 88 which align with the mounting apertures 82 of the base housing 44 and with the screw bosses 84 of the upper housing 46. Threaded fasteners 90 pass through the mounting apertures 82 and the mounting apertures 88 and tighten directly into the screw bosses 84. In some embodiments, a damping material, such as elastomeric dampers (not shown), can be positioned between the mounting structures 86 and the screw bosses 84, and/or between the mounting structures 86 and the base housing 44, to attenuate transmission of vibrations to the PCBA 66 which is supported by the central frame 64.

With reference again to FIG. 5, the second battery receptacles 56 are at least partially defined by sleeves 92 which receive the post portions of the second battery packs 14B. Each sleeve 92 is mounted directly to the central frame 64. In conventional battery chargers, the sleeve is directly mounted to the housing assembly rather than to a central frame. In the illustrated battery charger 10, the sleeve 92 is fastened directly to the central frame 64 via threaded fasteners. The upper housing 46 defines a receptacle aperture 94 (FIG. 1) that receives a rim of the sleeve 92. This improves manufacturability and assembly of the battery charger 10. This also significantly reduces a length of the wires (not shown) extending between the PCBA 66 and the second battery receptacles 56.

With reference to FIGS. 5 and 7, the central frame 64 includes a fan mount 96 that is centrally located adjacent the sleeves 92 and opposite from the rim 70. In the illustrated embodiment, the fan mount 96 supports two fans 68, including a first fan 68A and a second fan 68B. In some embodiments, the central frame 64 can include dampers, such as elastomeric dampers (not shown), which are positioned between the fan mount 96 and the fans 68 to attenuate transmission of vibrations from the fans 68 to the fan mount 96 and reduce audible fan noise. The fan mount 96 also defines the screw bosses 78 to which the upper housing 46 directly fastens. The central frame 64 further includes duct walls 98 that extend from the rim 70 to the fan mount 96. The duct walls 98 provide ducting for the airflow generated by the fans 68. For example, with reference to FIG. 1, the base housing 44 defines a plurality of vent apertures, including vent apertures 100A (or inlet apertures 100A) located at the first and second ends 20, 22, and vent apertures 100B (or inlet apertures 100B) located at the front and rear sides 24, 26. Together, the base housing 44 and the duct walls 98 of the central frame 64 cooperate to define an airflow passageway 102 that extends from the vent apertures 100A, 100B to the fan mount 96. The particular structure of the duct walls 98, including any recesses and wall orientations thereof, functions to define the airflow passageway 102 and direct the airflow toward particular components of the charging electronics 72 to prioritize cooling to those components.

With reference to FIG. 7, the fans 68 direct a cooling airflow 104 from the airflow passageway 102 upward to a plenum 106 located above the fan mount 96. The plenum 106 is defined by the upper housing 46 and the fan mount 96. More specifically, the plenum 106 is at least partially defined by each of the first upper housing member 48, the second upper housing member 50, and the central upper housing member 52. The first battery receptacles 54 are located adjacent the plenum 106. The central upper housing member 52, or more specifically, the first upper housing member 48 and the second upper housing member 50, define vent apertures 108 (or outlet apertures 108) adjacent each first battery receptacle 54 and fluidly communicating with the plenum 106. The vent apertures 108 allow the cooling airflow generated by the fans 68 to flow out the vent apertures 108 and cool the first battery packs 14A coupled to the first battery receptacles 54A.

In operation, the fans 68 generate a combined cooling airflow 104 that actively cools the PCBA 66, including the charging electronics 72, and also actively cools the first battery packs 14A when they are coupled to the first battery receptacles 54A. The cooling airflow 104 enters the housing assembly 18 via the vent apertures 100A, 100B, and flows through the airflow passageway 102 toward the fans 68 at the fan mount 96. The cooling airflow 104 flows across the PCBA 66 to actively cool the PCBA 66, including the charging electronics 72, as it moves through the airflow passageway 102. The cooling airflow 104 then flows through the fan mount 96 and the fans 68 and into the plenum 106. Finally, the cooling airflow 104 flows from the plenum 106 outward toward the first battery packs 14A via the vent apertures 108. The cooling airflow 104 exiting the vent apertures 108 cools the first battery packs 14A, which are coupled to the first battery receptacles 54A and being charged by the battery charger 10. Thus, the cooling airflow 104 also actively cools the second battery packs 14B during charging. In some examples, the first battery packs 14A may include battery pack apertures (not shown) that align with the vent apertures 108 when the first battery packs 14A are coupled to the first battery receptacles 54A. The cooling airflow 104 can flow directly into the first battery packs 14A via the battery pack apertures to improve cooling of the first battery packs 14A. In other examples, when the second battery packs 14B are coupled to the second battery receptacles 56, the cooling airflow 104 flows outward from the vent apertures 108 toward the second battery packs 14B to actively cool the second battery packs 14B. As shown in FIG. 7, the fan mount 96 substantially isolates the airflow passageway 102 from the plenum 106, which prevents airflow recirculation within the battery charger 10 to improve cooling.

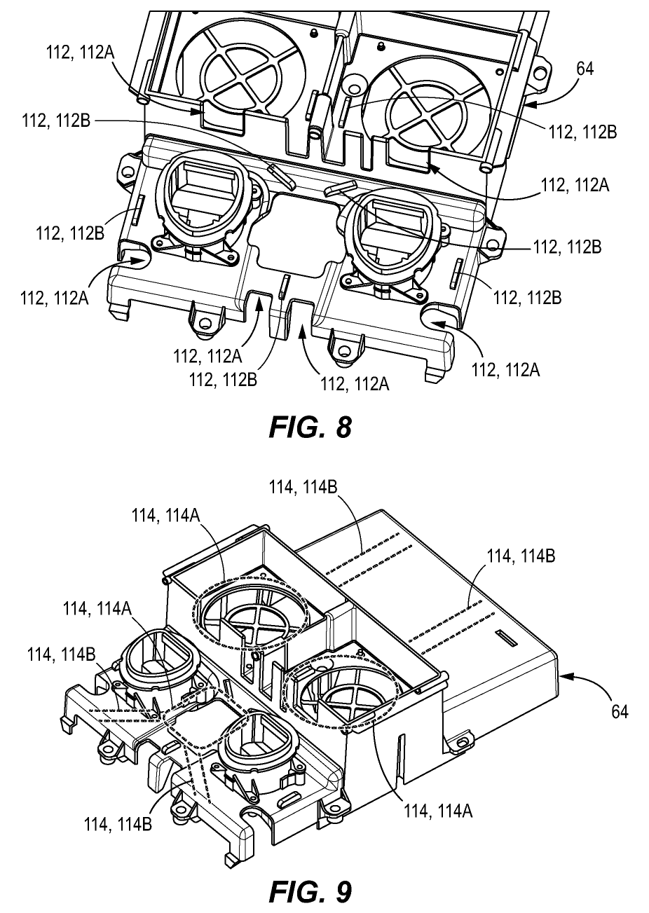

With reference to FIG. 8, the central frame 64 includes multiple wire routing features 112 to direct wires (not shown) extending between the PCBA 66 and the first battery receptacles 54 and second battery receptacles 56. The wire routing features 112 also direct wires for the fans 68, the AC power cord (not shown), and other secondary PCBAs, such as the LED indicator PCBA (not shown). The wire routing features 112 include apertures 112A defined in the duct walls 98 and the fan mount 96 to permit the wires to pass therethrough. The wire routing features 112 also include anchors 112B to which fasteners (e.g., zip ties) can be attached to secure the wires.

With reference to FIG. 9, the central frame 64 further includes water mitigation features 114 to direct water away from sensitive components, such as the charging electronics 72. The water mitigation features 114 include ribs 114A defined in the duct walls 98. The water mitigation features 114 also include angled surfaces 114B defined in the duct walls 98.

Although the disclosure has been described in detail with reference to certain preferred embodiments, variations and modifications exist within the scope and spirit of one or more independent aspects of the disclosure as described. Various features and/or advantages of the disclosure are set forth in the following claims.

What is claimed is:

1. A battery charger operable to charge a battery pack, the battery charger comprising:
a housing assembly;
a printed circuit board assembly positioned within the housing assembly, the printed circuit board assembly including charging electronics operable to output a charging current to charge the battery pack;
a central frame positioned within the housing assembly and directly coupled to the printed circuit board assembly; and
a fan operable to generate an airflow through the housing assembly, the fan directly coupled to the central frame;
wherein the central frame is directly fastened to the housing assembly.

2. The battery charger of claim 1, wherein:
the housing assembly includes a base housing and an upper housing;
the upper housing is directly fastened to the central frame; and
the base housing is fastened to the upper housing.

3. The battery charger of claim 2, wherein a portion of the central frame is clamped between the base housing and the upper housing.

4. The battery charger of claim 1, wherein the central frame defines a rim that contacts and surrounds an outer periphery of the printed circuit board assembly.

5. The battery charger of claim 4, wherein the printed circuit board assembly is mounted to the rim using threaded fasteners.

6. The battery charger of claim 1, wherein the fan is mounted to a fan mount defined by the central frame.

7. The battery charger of claim 1, wherein the airflow actively cools the printed circuit board assembly, and wherein the airflow also actively cools the battery pack when the battery pack is coupled to the housing assembly.

8. A battery charger operable to charge a battery pack, the battery charger comprising:
a housing assembly;
a printed circuit board assembly positioned within the housing assembly and including charging electronics operable to output a charging current to charge the battery pack;
a central frame positioned within the housing assembly and directly coupled to the printed circuit board assembly; and
a fan operable to generate an airflow through the housing assembly;
wherein the airflow actively cools the printed circuit board assembly; and
wherein the airflow actively cools the battery pack when the battery pack is coupled to the housing assembly.

9. The battery charger of claim 8, wherein:
the housing assembly includes a base housing and an upper housing;
the upper housing is directly fastened to the central frame; and
the base housing is fastened to the upper housing.

10. The battery charger of claim 9, wherein:
the central frame includes a fan mount and a duct wall;
the base housing defines a plurality of inlet apertures; and
an airflow passageway is defined between the duct wall and the base housing and extends from the plurality of inlet apertures to the fan mount.

11. The battery charger of claim 10, further comprising a plenum defined by the upper housing and the fan mount and positioned downstream of the fan.

12. The battery charger of claim 11, wherein the upper housing further defines an outlet aperture and a battery receptacle configured to engage the battery pack, and wherein the airflow exits the plenum through the outlet aperture and toward the battery pack.

13. The battery charger of claim 12, wherein the fan mount divides the airflow passageway from the plenum.

14. The battery charger of claim 8, wherein the charging electronics include a controller configured to selectively activate the fan in response to a detected temperature of the printed circuit board assembly exceeding a threshold temperature.

15. A battery charger operable to charge a battery pack, the battery charger comprising:
a housing assembly having a base housing and an upper housing;
a central charging assembly positioned within the housing assembly, the central charging assembly including:
a central frame,
a printed circuit board assembly mounted to the central frame, and
a fan mounted to the central frame; and
a battery receptacle mounted to the central frame and configured to removably couple to the battery pack.

16. The battery charger of claim 15, wherein the central frame includes a sleeve defining at least portion of the battery receptacle.

17. The battery charger of claim 15, wherein the upper housing is fastened directly to the central frame independently of the base housing.

18. The battery charger of claim 17, wherein a portion of the central frame is clamped between the base housing and the upper housing.

19. The battery charger of claim 15, wherein:
the fan is operable to generate an airflow through the housing assembly;
the airflow actively cools the printed circuit board assembly; and
the airflow actively cools the battery pack when the battery pack is coupled to the battery receptacle.

20. The battery charger of claim 15, wherein the central frame defines a rim that contacts and surrounds an outer periphery of the printed circuit board assembly.
